(19) United States
(12) Patent Application Publication
(10) Pub. No.: US 2002/0097100 A1
(43) Pub. Date: Jul. 25, 2002

(54) Optimally designed dielectric resonator oscillator (DRO) and method therefor

(76) Inventors: Donnie W. Woods, Thousand Oaks, CA (US); Charles D. Pitcher, Thousand Oaks, CA (US); Roy Baldarrama, Camarillo, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/771,353

(22) Filed: Jan. 25, 2001

(51) Int. Cl. H03B 5/18

(52) U.S. Cl. 331/99; 331/74; 331/117 D; 331/117 FE; 331/177 V

(57) ABSTRACT

A design methodology for a DRO that facilitates the development of the DRO. The methodology involves providing an electrical length of approximately 180 degrees or a multiple thereof from a region interior to a field effect transistor to a puck-resonator line interaction region, providing an electrical length of approximately 180 degrees or a multiple thereof from a region interior to the field effect transistor to the signal end of a source feedback transmission line, and providing an electrical length of approximately 90 degrees or an odd multiple thereof from a varactor diode signal ground to a puck-tuning line interaction region. Other aspects relate to a DRO resonator transmission line and a DRO tuning transmission line having a portion formed on a higher dielectric substrate to concentrate the electromagnetic field, and a portion on a lower dielectric substrate to expand the electromagnetic field near the dielectric resonator puck.

### FIELD OF THE INVENTION

This invention relates generally to radio frequency (RF)/microwave/millimeterwave circuits, and in particular, to an optimally designed dielectric resonator oscillator (DRO) and method therefor.

### BACKGROUND OF THE INVENTION

Dielectric resonator oscillators (DROs) are used extensively in the wireless communications field. In particular, DROs are used as local oscillators for down-converting a radio frequency (RF)/microwave/millimeterwave signal to a lower-frequency intermediate or baseband signal, and for up-converting an intermediate or baseband signal to a higher-frequency RF/microwave/millimeterwave signal. DROs are preferred over other types of oscillators because DROs have improved phase noise characteristics and are capable of achieving such improved characteristics at relatively high frequencies, such as at 20 GHz or above.

A drawback of DROs is that their design, development and manufacturing are typically plagued with a substantial amount of trial and error to get them to achieve a desired specification. For example, the placement of the dielectric resonator puck from the gate of the field effect transistor (FET) is typically subject to lots of trial and error to obtain the desired performance. Also, the placement of the dielectric resonator puck with respect to the resonator line is subject to lots of trial and error to obtain the desired performance. Furthermore, the placement of the dielectric resonator puck with respect to the tuning line is subject to lots of trial and error to obtain the desired performance. Because the design, development and manufacturing of DROs requires substantial trial and error, DROs are typically very expensive and the manufacturing lead times are relatively long.

Thus, there is a need for a method of designing a DRO that results in less trial and error in the design, development, and manufacturing of the DRO. Such a need and others are met with the method of designing a DRO and the resulting DRO of the invention.

### SUMMARY OF THE INVENTION

An aspect of the invention relates to a method of designing a dielectric resonator oscillator (DRO) and a resulting DRO that requires less trial and error in the design, development, and manufacturing of the DRO. The design methodology for the DRO involves:

(1) providing an electrical length at the DRO's operating frequency of approximately 180 degrees or an integer multiple thereof from a region interior to a field effect transistor to a region situated at the intersection of the mid-height plane and the circumference of the dielectric resonator puck that is closest to the resonator transmission line, referred to herein as the “puck-resonator line interaction region”,

(2) providing an electrical length at the DRO's operating frequency of approximately 180 degrees or an integer multiple thereof from a region interior to the field effect transistor to the signal end of a source feedback transmission line connected to the source (S) of the field effect transistor, and

(3) providing an electrical length at the DRO's operating frequency of approximately 90 degrees or an odd integer multiple thereof from a signal ground that substantially grounds a varactor diode terminal (e.g. cathode or anode) to a region situated at the intersection of the mid-height plane and the circumference of the dielectric resonator puck that is closest to the tuning transmission line, referred to herein as the “puck-tuning line interaction region”. The 90 degree electrical length (or odd integer multiple thereof) occurs when the varactor diode is operated such that the range of the extremes of the electrical length (from the varactor signal ground to the puck-tuning line interaction region) resulting from the varactor diode being operated at the respective extremes of the desired tuning voltage range applied to the varactor diode are substantially symmetrically centered about the 90 degree electrical length.

A portion of the tuning transmission line extending from the region on the tuning transmission line closest to the puck-tuning line interaction region to the open end is set to an electrical length that allows the electrical length from a signal ground that substantially grounds a varactor diode terminal (e.g. cathode or anode) to the puck-tuning line interaction region to be at substantially 90 degrees (or odd integer multiple thereof) when the varactor diode is operated such that the range of the extremes of the electrical length (from the varactor signal ground to the puck-tuning line interaction region) resulting from the varactor diode being operated at the respective extremes of the desired tuning voltage range are substantially symmetrically centered about the 90 degree electrical length.

More specifically, the first design guideline of providing an electrical length at the DRO's operating frequency of approximately 180 degrees or an integer multiple thereof from a region interior to a FET to the puck-resonator line interaction region involves dissecting the path into first and second electrical lengths. The first electrical length EL₁ extends down the resonator transmission line from a region interior to the FET to a region on the resonator transmission line that is closest to the puck-resonator line interaction region. The second electrical length EL₂ extends through the air from the region on the resonator line closest to the puck-resonator line interaction region to the puck-resonator line interaction region. The sum of the first and second electrical lengths EL₁ and EL₂ is set to be approximately 180 degrees. The second design guideline is that of providing an electrical length EL₃ at the DRO's operating frequency of approximately 180 degrees or an integer multiple thereof from a region interior to the FET to the signal end of a source feedback transmission line.

The electrical length from the puck to the interior region of the FET (EL₁ and EL₂) and from the interior region of the FET to the signal end of a source feedback transmission line (EL₃) are each set to approximately 180 degrees so that the output power of the DRO is substantially maximized, or optionally, the output phase noise of the DRO is substantially minimized.

The third design guideline of providing an electrical length at the DRO's operating frequency of approximately 90 degrees or an odd integer multiple thereof from the signal ground that substantially grounds the varactor diode terminal (e.g. cathode or anode) to the puck-tuning line interaction region involves dissecting the path up into a fourth electrical length EL₄ and a fifth electrical length EL₅. The fourth electrical length EL₄ extends along the tuning transmission line from the signal ground that substantially grounds the varactor diode terminal (e.g. cathode or anode) to a region on the tuning transmission line that is closest to the puck-tuning line interaction region. The fifth electrical length EL₅ extends through the air from the region on the tuning transmission line that is closest to the puck-tuning line interaction region to the puck-tuning line interaction region. The sum of the fourth and fifth electrical lengths EL₄ and EL₅ is set to position the center of the range of electrical lengths (resulting from the desired voltage tuning range applied to the varactor diode) from the puck-tuning line interaction region to the varactor diode terminal (e.g. cathode or anode) that is substantially grounded at substantially 90 degrees or an odd integer multiple thereof.

A portion of the tuning transmission line extending from the region on the tuning transmission line closest to the puck-tuning line interaction region to the open end is set to have an electrical length that allows the sum of electrical lengths EL₄+EL₅, to substantially equal 90 degrees (or odd integer multiple thereof) when the varactor diode is operated such that the range of the extremes of the electrical length (from the varactor signal ground to the puck-tuning line interaction region) resulting from the varactor diode being operated at the respective extremes of the desired tuning voltage range are substantially symmetrically centered about the 90 degree electrical length.

Using the aforementioned design guidelines, a DRO can be developed, manufactured and tested with reduced trial and error time and efforts expended to obtain substantially optimum performance for the DRO. In the designing and development of a DRO, a designer may analyze and configure the DRO such that the above design guidelines are met. In manufacturing, an assembly person merely places the dielectric resonator puck with, optionally, a pre-determined stand-off at an indicated location which meets the above design guidelines. In testing, an engineer or technician merely checks whether the performance of the DRO is at the desired performance specification, which it should be because the design guidelines are intended to achieve substantially optimum performance for the DRO. Otherwise, the engineer or technician merely performs minor tuning on the DRO to achieve the desired performance specification. The development, manufacturing, and testing process is much simpler, requires less time to complete, and substantially reduces the costs of DROs.

Another aspect of the invention relates to a method of designing a DRO and the resulting DRO that can generate an output signal with a substantial reduction in phase noise. Specifically, the design methodology involves designing a portion of a resonator and/or tuning transmission line to be disposed on a first substrate having a first dielectric constant, and a second portion of the resonator and/or tuning transmission line to be disposed on a second substrate having a second dielectric constant that is substantially less than the first dielectric constant of the first substrate. The portion of the resonator and/or tuning transmission line on the lower dielectric substrate is situated adjacent to the dielectric resonator puck to electromagnetically interact therewith. It is theorized that the improvement in phase noise is due to the electromagnetic field being concentrated in and confined around the higher dielectric substrate to minimize electromagnetic interference with the field surrounding the dielectric resonator puck, and then the electromagnetic field is allowed to expand around the lower dielectric substrate allowing the electromagnetic field to interact efficiently with the field surrounding the dielectric resonator puck.

Other aspects of the invention relate to a receiver or transmitter that uses the DROs of the invention. Additional aspects, features and techniques of the invention will become apparent to those skilled in the relevant art in view of the following detailed description of the invention.

### BRIEF DESCRIPTION OF THE DRAWINGS

FIG. 1 illustrates a block diagram of an exemplary dielectric resonator oscillator (DRO) in accordance with the invention;

FIG. 2A illustrates a side view of the resonator transmission line and dielectric resonator puck portion of the exemplary DRO of the invention;

FIG. 2B illustrates a front view of the resonator and tuning transmission lines and the dielectric resonator puck portion of the exemplary DRO of the invention;

FIG. 3 illustrates a side view of the tuning transmission line portion of the exemplary DRO of the invention;

FIG. 4 illustrates a block diagram of another exemplary dielectric resonator oscillator (DRO) in accordance with the invention;

FIG. 5 illustrates a block diagram of an exemplary receiver using one or more dielectric resonator oscillators (DROs) in accordance with the invention; and

FIG. 6 illustrates a block diagram of an exemplary transmitter using one or more dielectric resonator oscillators (DROs) in accordance with the invention.

### DETAILED DESCRIPTION OF THE INVENTION

FIG. 1 illustrates a block diagram of an exemplary dielectric resonator oscillator (DRO) 100 in accordance with the invention. The DRO 100 comprises a field effect transistor (FET) 102 having gate (G), drain (D), and source (S) ports, an output impedance matching circuit 104 coupled to the drain (D) of the FET 102, and a source feedback transmission line 106 coupled to the source (S) of the FET 102. The DRO 100 further comprises a drain bias circuit 108 for routing the drain bias voltage (Vd) to the drain (D) of the FET 102 while isolating the DRO signal from the drain bias circuit 108. Also, the DRO 100 comprises a source bias circuit 110 for routing the source bias voltage (Vs) to the source (S) of the FET 102 while isolating the DRO signal from the source bias circuit 110.

The DRO 100 further comprises a resonator transmission line 112 having one end coupled to the gate (G) of the FET 102 and another end terminated with an impedance element having a characteristic impedance Z₀ (e.g. 50 Ohms) substantially the same as the characteristic impedance of the resonator transmission line 112. Additionally, the DRO 100 comprises a tuning transmission line 116 having one end coupled to a varactor diode 118 and the other end being open. The DRO 100 includes a tune voltage bias circuit 120 for routing the frequency tuning voltage V_{TUNE} to the cathode of the varactor diode 118 while isolating the DRO signal from the tune voltage bias circuit 120. A varactor grounding circuit 122 is provided to ground the anode of the varactor diode 118 while isolating the DRO signal from the varactor grounding circuit 122. A signal bypass capacitor C is provided to substantially signally ground a terminal (e.g. in this case the cathode) of the varactor diode 118. The DRO 100 further comprises a dielectric resonator puck 114 situated between and electromagnetically coupled to the resonator transmission line 112 and the tuning transmission line 116.

As previously discussed, a drawback of prior art DROs is that their design, development and manufacturing are typically plagued with a substantial amount of trial and error to get them to achieve a desired specification. For example, the placement of the dielectric resonator puck from the gate (G) of the field effect transistor (FET) is subject to lots of trial and error to obtain the desired performance. Also, the placement of the dielectric resonator puck with respect to the resonator transmission line is subject to lots of trial and error to obtain the desired performance. Furthermore, the placement of the dielectric resonator puck with respect to the tuning line is subject to lots of trial and error to obtain the desired performance. Because the design, development and manufacturing of prior art DROs require substantial trial and error, DROs are typically very expensive and the manufacturing lead times are relatively long.

To improve on these drawbacks of prior art DROs, a method of designing a DRO 100 is provided herein in accordance with the invention which can substantially reduce the trial and error time and efforts expended in achieving a desired performance specification for the DRO 100. Specifically, the DRO design methodology involves configuring the DRO 100:

(1) to provide an electrical length at the operating frequency f₀ of approximately 180 degrees or an integer multiple thereof from a region interior to the FET 102 to a region 115 situated at the intersection of the mid-height plane and the circumference of the dielectric resonator puck 114 that is closest to the resonator transmission line 112 (the “puck-resonator line interaction region”).

(2) to provide an electrical length at the operating frequency f₀ of approximately 180 degrees or an integer multiple thereof from a region interior to the FET 102 to the signal end of the source feedback transmission line 106.

The electrical length from the puck 114 to the interior region of the FET 102 (EL₁ and EL₂) and from the interior region of the FET 102 to the signal end of a source feedback transmission line 106 (EL₃) are each set to approximately 180 degrees so that the output power of the DRO 100 is substantially maximized, or optionally, the output phase noise of the DRO 100 is substantially minimized.

(3) to provide an electrical length at the operating frequency f₀ of approximately 90 degrees or an odd integer multiple thereof from the signal ground that substantially grounds a terminal (e.g. in this case the cathode) of the varactor diode 118 to the intersection of the mid-height plane and the circumference of the dielectric resonator puck 114 that is closest to the tuning transmission line 116 (the “puck-tuning line interaction region”). The 90 degree electrical length (or odd integer multiple thereof) occurs when the varactor diode is operated such that the range of the extremes of the electrical length (from the varactor signal ground to the puck-tuning line interaction region) resulting from the varactor diode being operated at the respective extremes of the desired tuning voltage range are substantially symmetrically centered about the 90 degree electrical length.

As part of the third design guideline, a portion of the tuning transmission line 116 extending from the region 117 on the tuning transmission line 116 closest to the puck-tuning line interaction region 119 to the open end is set to have an electrical length EL₆ that allows the sum of electrical lengths EL₄+EL₅ to substantially equal 90 degrees (or odd integer multiple thereof) when the varactor diode is operated such that the range of the extremes of the electrical length (from the varactor signal ground to the puck-tuning line interaction region) resulting from the varactor diode being operated at the respective extremes of the desired tuning voltage range are substantially symmetrically centered about the 90 degree electrical length. The discussion of these design guidelines for the DRO 100 is better explained with reference to FIGS. 1, 2A-2B, and 3.

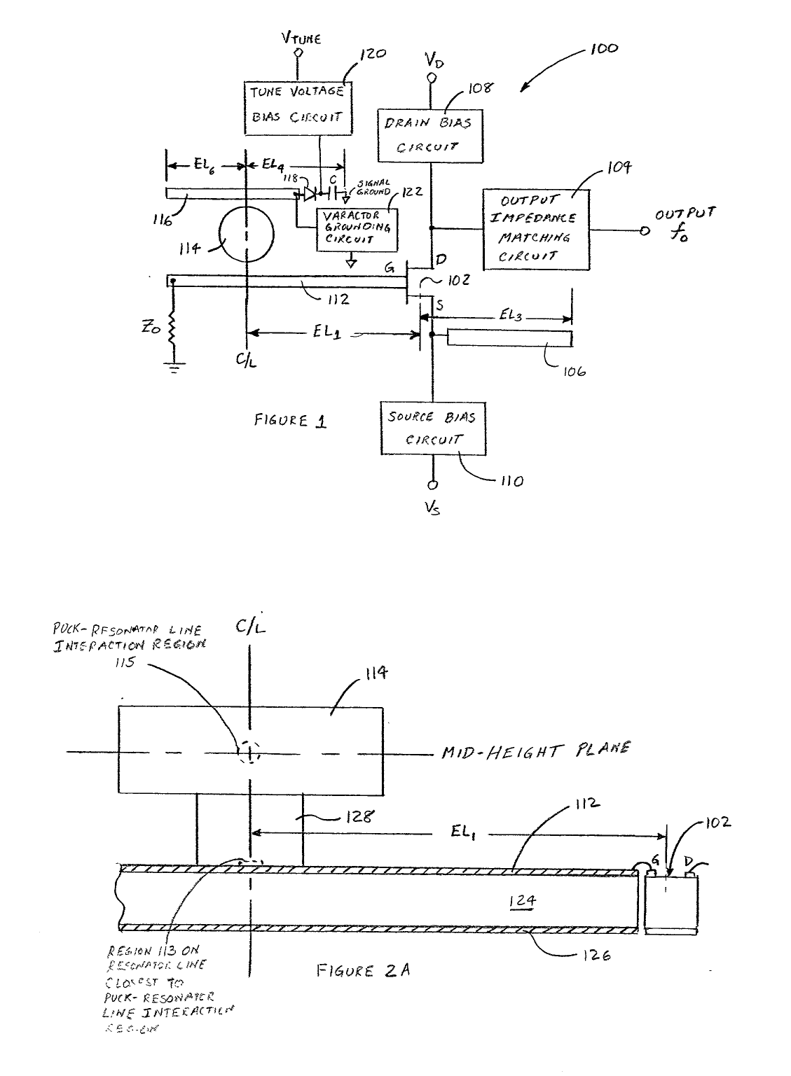

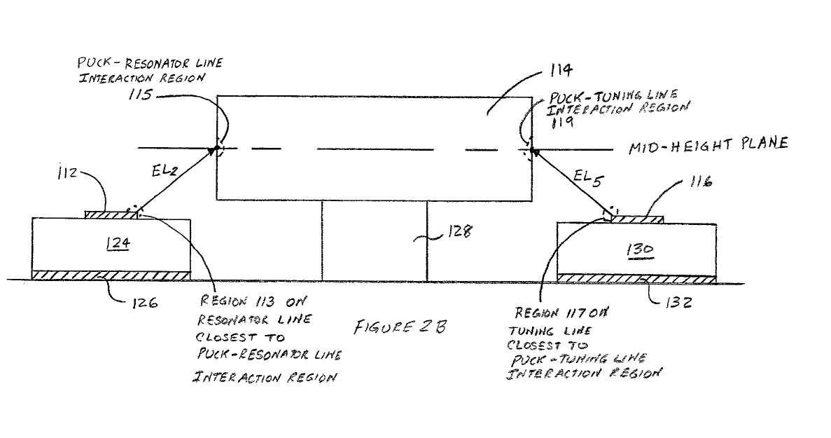

FIGS. 2A-2B illustrate a side view of the resonator transmission line and a front view of the resonator and tuning transmission lines and dielectric resonator puck portion of the exemplary DRO 100 of the invention. As shown, the resonator transmission line 112 may be configured as a microstrip line having a dielectric substrate 124 (e.g. alumina, quartz, Duroid®, or other suitable substrate for microstrip) with an underside grounding plane 126. An end of the resonator transmission line 112 is wire or ribbon bonded to the gate (G) pad of the FET 102 with or without an intervening capacitor. The dielectric resonator puck 114 is typically cylindrical in shape and can be optionally disposed on a stand-off 128.

To analyze the first design guideline of providing an electrical length at the operating frequency f₀ of approximately 180 degrees or an integer multiple thereof from a region interior to the FET 102 to the puck-resonator line interaction region 115, the path can be divided up into a first electrical length EL₁ which extends down the resonator transmission line 112 from the interior region of the FET 102 to a region 113 on the resonator transmission line 112 that is closest to the puck-resonator line interaction region 115, and a second electrical length EL₂ which extends through the air from the region 113 of the resonator transmission line 112 to the puck-resonator line interaction region 115. Accordingly, the following relationship approximately holds:

EL₁+EL₂=J×180 degrees Eq. 1

where J is an integer number.

The second design guideline is that of providing an electrical length EL₃ at the operating frequency f₀ of approximately 180 degrees or an integer multiple thereof from a region interior to the FET 102 to the signal end of the source feedback transmission line 106. The signal end of the source feedback transmission line 106 can be an open end as shown in FIG. 1, or a shorted end, or other impedance that results in the electrical length EL₃ at the operating frequency f₀ being approximately 180 degrees from a region interior to the FET 102 to the signal end of the source feedback transmission line 106. Accordingly, the following relationship substantially holds:

EL₃=K×180 degrees Eq. 2

where K is an integer number.

The purpose of the first and second design guidelines is illustrated by the following description of the operation of an oscillator circuit.

An oscillator circuit produces its oscillation frequency by selectively amplifying the signal at a specific frequency. The signal is initially only one of many signals represented as noise within the transistor but the other signals will not be amplified to the same degree by the oscillator circuitry. The oscillator circuit is configured to amplify a signal that is able to travel from the transistor or other amplifying device out to a region or regions at which the signal is substantially reflected and return to the transistor substantially in-phase (e.g. a total phase shift of 0, 360, 720, etc. electrical degrees). The amplitude of the signal is typically increased until the oscillator reaches saturation.

When the oscillator is first energized, the FET 102 will supply an output spectrum that is substantially low in power and substantially resembles a white noise spectrum. This spectrum will exit out all three ports of the FET 102, i.e. the gate (G), the drain (D), and the source (S). The spectrum exiting the drain (D) will substantially pass through the output impedance matching circuit 104 and leave the oscillator at the oscillator's output port. The spectrum exiting the source (S) will substantially enter the source feedback transmission line 106 and be reflected back towards the source (S) of FET 102. The spectrum exiting the gate (G) will substantially be transmitted along the length of the resonator transmission line 112. The signal with a frequency at which the resonator puck 114 is resonant will couple a portion of its energy to the resonator puck 114. The signal that couples to the puck will be reflected and the signal will substantially couple onto the resonator transmission line 112. A portion of the signal will travel into the grounded impedance termination Z₀, while the remainder will travel on the resonator transmission line 112 back to the gate (G) of FET 102.

The circuitry will preferentially amplify the signal that is able to travel from the region in the FET 102 wherein the initial noise spectrum is generated to both the resonator puck 114 and back, and to the end of the source feedback circuit 106 and back, and return with a phase that is substantially in-phase with the signal that is present in the FET 102 (i.e. with a phase shift that is a multiple of 360 degrees). Frequencies that do not have the proper phase shift will receive less amplification. The signal present at the gate (G) will be increased by the gain present in the FET 102 and supply a signal with an increased amplitude out both the drain (D) and the source (S) of the FET 102. The increased amplitude at the drain (D) will result in an increase in the amplitude of the oscillator output signal at the oscillator's output port. The increased signal at the source (S) will substantially enter the source feedback transmission line 106, be reflected at the end of the source feedback transmission line 106 back toward the source (S) of the FET 102 and pass through the FET 102 exiting out the drain (D) and the gate (G) of the FET 102. The level of the signal exiting the gate (G) of the FET 102 will be greater than the level of the signal entering the gate (G) resulting in a larger signal reflected back from the puck 114. The amplitudes of the signals present at the gate (G), source (S) and drain (D) of FET 102 will increase until the oscillator reaches saturation.

FIG. 3 illustrates a side view of the tuning transmission line and dielectric resonator puck portion of the exemplary DRO 100 of the invention. As shown, the tuning transmission line 116 may be configured as a microstrip line having a dielectric substrate 130 (e.g. alumina, quartz, Duroid®, or other suitable substrate for microstrip) with an underside grounding plane 132. An end of the tuning transmission line 116 is wire or ribbon bonded to the anode of the varactor diode 118 with or without an intervening capacitor, and the other end is open. The cathode of the varactor diode 118 is coupled to signal ground via the bypass capacitor C.

To analyze the third design guideline of providing an electrical length at the operating frequency f₀ of approximately 90 degrees or an odd integer multiple thereof from the signal ground that substantially grounds a terminal (in this case the cathode) of the varactor diode 118 to the puck-tuning line interaction region 119 first involves dissecting the electrical paths into a fourth electrical length EL₄ which extends down the tuning transmission line 116 from the signal ground that substantially grounds a terminal (in this case the cathode) of the varactor diode 118 to region 117 of the tuning transmission line 116 that is closest to the puck-tuning line interaction region 119, and a fifth electrical length EL₅ which extends through the air from the region 117 of the tuning transmission line 116 to the puck-tuning line interaction region 119. Also, an additional electrical length EL₆ can be defined from the open end of the tuning transmission line 116 to the region 117.

Second, the range of the electrical lengths ΔEL₄₋₅(ΔV_{TUNE}) from the puck-tuning line interaction region 119 to the signal ground that substantially grounds a terminal (in this case the cathode) of the varactor diode 118 that corresponds to the voltage tuning range ΔV_{TUNE} is determined. This is accomplished by varying the varactor tuning voltage V_{TUNE} across its desired operating range, and observing the resulting range of electrical lengths ΔEL₄₋₅(ΔV_{TUNE}) from the puck-tuning line interaction region 119 of the puck 114 to the signal ground that substantially grounds a terminal (in this case the cathode) of the varactor diode 118 that is coupled to ground.

Third, the electrical lengths EL₄, EL₅ and EL₆ are set such that the substantial center of the electrical length range ΔEL₄₋₅(ΔV_{TUNE}) having extremes corresponding to the extremes of the voltage tuning range applied to the varactor diode is substantially at 90 degrees or an odd multiple thereof. Thus, the following relationship approximately holds:

EL₄+EL₅ [symbol] =center of ΔEL₄₋₅(ΔV_{TUNE})=M×90 degrees Eq. 3

where M is an odd integer number. It shall be noted that varying the electrical length EL₆ from the open end to the region 117 of the tuning transmission line 116 affects the electrical length associated with the electrical lengths EL₄+EL₅. For example, in one case a particular electrical length EL₆ may result in the sum of electrical lengths EL₄+EL₅ of approximately 90 degrees. In another case where the electrical length EL₆ is different than it was in the previous case, the sum of electrical lengths EL₄+EL₅ may be about 270 degrees.

With the aforementioned design guidelines whose relationships have been set forth in equations 1-3, the DRO 100 of the invention can be developed, manufactured and tested with reduced trial and error to obtain substantially optimum performance for the DRO 100. In developing a DRO, a designer may analyze and configure the DRO such that the above conditions set forth in guidelines 1-3 and equations 1-3 are met. In manufacturing, an assembly person merely places the dielectric resonator puck with, optionally, a pre-determined stand-off at an indicated location which meets the conditions set forth in guidelines 1-3 and equations 1-3. In testing, an engineer or technician merely checks whether the performance of the DRO is at the desired performance specification, which it should be because the design guidelines are intended to achieve substantially optimum performance for the DRO. Otherwise, the engineer or technician merely performs minor tuning on the DRO to achieve the desired performance specification. The development, manufacturing, and testing process is much simpler, requires less time to complete, and substantially reduces the costs of DROs.

The design guidelines as set forth in equations 1-3 may apply for other types of DRO configurations. DRO 100 uses a common source series feedback configuration. However, the design guidelines are also applicable to a common gate series feedback DRO and a common drain series feedback DRO. The active device 102 need not be limited to FET technology, but can encompass other types of transistors including bipolar (I checked the spelling of “bipolar” in a dictionary) technology, heterojunction bipolar technology, high electron mobility transistor (HEMT) technology, and others. The resonator and tuning transmission lines need not be configured as microstrip lines, but can encompass other types of transmission lines, such as stripline, suspended microstrip, or co-planar waveguide.

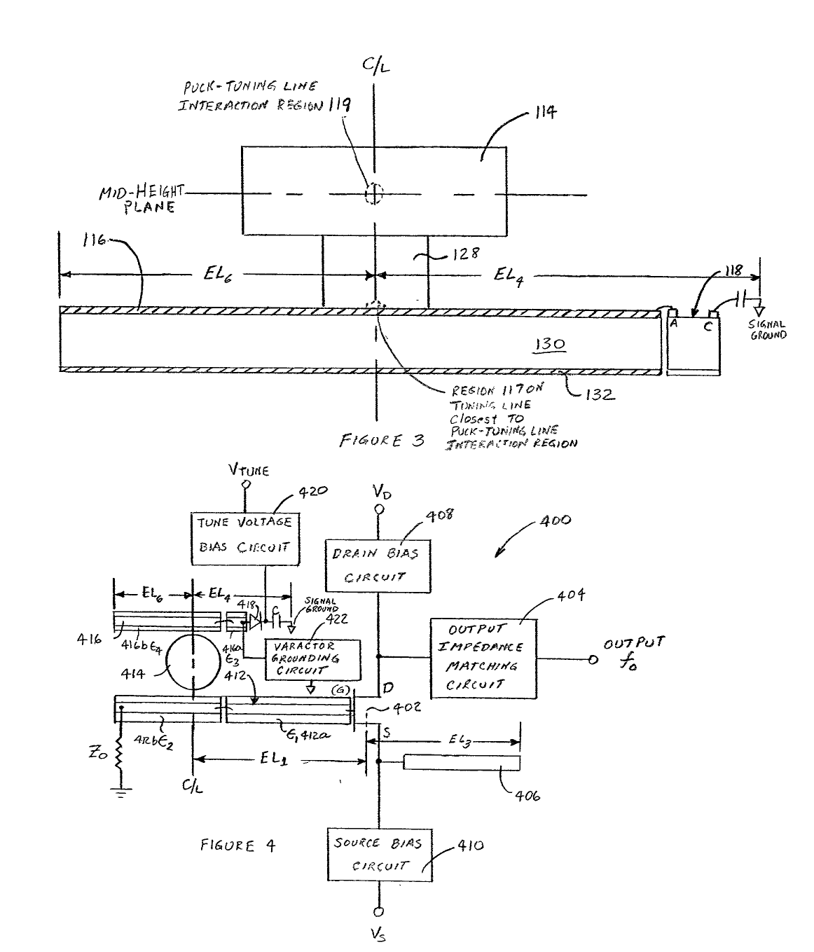

FIG. 4 illustrates a block diagram of another exemplary dielectric resonator oscillator (DRO) 400 in accordance with the invention. The DRO 400 is particularly useful in producing an output sinusoidal signal with relatively low phase noise. Similar to DRO 100, DRO 400 comprises a field effect transistor (FET) 402 having gate (G), drain (D), and source (S) ports, an output impedance matching circuit 404 coupled to the drain (D) of the FET 402, and a source feedback transmission line 406 coupled to the source (S) of the FET 402. The DRO 400 further comprises a drain bias circuit 408 for routing the drain bias voltage (Vd) to the drain (D) of the FET 402 while isolating the DRO signal from the drain bias circuit 408. Also, the DRO 400 comprises a source bias circuit 410 for routing the source bias voltage (Vs) to the source (S) of the FET 402 while isolating the DRO signal from the source bias circuit 410.

The DRO 400 further comprises a resonator transmission line 412 having one end coupled to the gate (G) of the FET 402 and another end terminating with an impedance element having a characteristic impedance Z₀ (e.g. 50 Ohms) substantially the same as the characteristic impedance of the resonator transmission line 412. Additionally, the DRO 400 comprises a tuning transmission line 416 having one end coupled to a varactor diode 418 and the other end being open. The DRO 400 includes a tune voltage bias circuit 420 for routing the frequency tuning voltage V_{TUNE} to the cathode of the varactor diode 418 while isolating the DRO signal from the tune voltage bias circuit 420. A varactor grounding circuit 422 is provided to ground the anode of the varactor diode 418 while isolating the DRO signal from the varactor grounding circuit 422. The DRO 400 further comprises a dielectric resonator puck 414 situated between and electromagnetically coupled to the resonator transmission line 412 and the tuning line 416.

The DRO 400 differs from DRO 100 in that the resonator transmission line 412 is formed as a microstrip line on two distinct substrates 412a and 412b. Substrate 412a, which includes the end of the resonator transmission line 412 coupled to the gate (G) of the FET 402, has a dielectric constant of ε₁. Substrate 412b, which includes the end of the resonator transmission line 412 coupled to impedance element Z₀, has a dielectric constant of ε₂. One or more wire or ribbon bonds may connect the portion of resonator transmission line 412 disposed on substrate 412a to the portion of the resonator transmission line 412 disposed on substrate 412b. Substrate 412b is situated adjacent to the dielectric resonator puck 414 to provide more electromagnetic interaction of the puck 414 with the portion of the resonator transmission line 412 on substrate 412b.

It has been observed that the phase noise of the DRO 400 is substantially reduced (e.g. by as much as 6 dB) if the dielectric constant ε₁ of substrate 412a is substantially higher than the dielectric constant ε₂ of substrate 412b. For example, substrate 412a can be formed of alumina which has a relative dielectric constant ε₁ of about 9.9, and substrate 412b can be formed of quartz which has a relative dielectric constant ε₂ of about 3.78. Accordingly, the following relationship substantially holds:

ε₁>>ε₂ Eq.4

It is theorized that the improvement in phase noise is due to the electromagnetic field being concentrated in and confined around the substrate 412a due to its higher dielectric constant ε₁, and then the electromagnetic field is allowed to expand around the substrate 412b due to its lower dielectric constant ε₂ allowing the electromagnetic field to interact more effectively with the electromagnetic field surrounding the dielectric resonator puck 414.

Similarly, the tuning transmission line 416 can be formed as a microstrip line on two distinct substrates 416a and 416b. Substrate 416a, which includes the end of the tuning transmission line 416 coupled to the varactor diode 418, has a relative dielectric constant of ε₃. Substrate 416b, which includes the open end of tuning transmission line 416 has a relative dielectric constant of ε₄. For the same reason as that given above for the resonator transmission line 412, the substrates 416a and 416b can be chosen according to the following equation:

ε₃ >>ε₄ Eq. 5

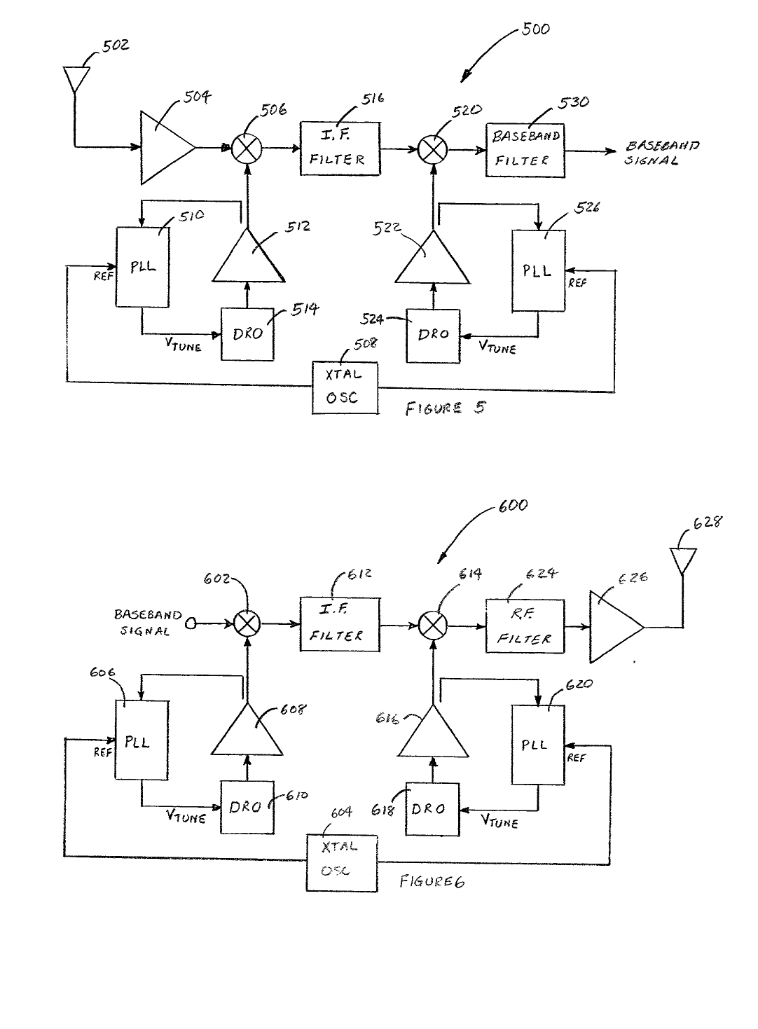

FIG. 5 illustrates a block diagram of an exemplary receiver 500 using one or more dielectric resonator oscillators (DROs) in accordance with the invention. The DROs 100 and 400 of the invention can be used in many applications, even as part of the receiver 500. The receiver 500 comprises a low noise amplifier 504 having an input for receiving an RF/microwave/millimeterwave signal from an antenna 502 or other receiving source. The output of the low noise amplifier 504 is coupled to a first down-converting stage comprising a first mixer 506 and a first local oscillator (LO) comprising DRO 514 (of the same type as DRO 100 and/or 400), optional amplifier 512 (or other device that isolates the output of the DRO 514 from the mixer 506, such as an attenuator or isolator), phase lock loop (PLL)510, and a reference crystal oscillator 508. The output of the DRO 514 is optionally coupled to the input of the amplifier 512, as required, for increasing the power of the local oscillator signal sufficiently to drive the mixer 506. A portion of the local oscillator signal at the input of the mixer 506 is coupled to the PLL 510 to phase compare the local oscillator signal with the reference from the crystal oscillator 508, and to generate a tuning voltage V_{TUNE} for the DRO 514 to keep the DRO output within a frequency specification.

The output of the mixer 506 is coupled to an intermediate frequency (IF) filter 516 to remove the higher frequency products and other unwanted signals from the down-converted received signal. If two-stage down-conversion is desired, the output of the IF filter 516 is coupled to a second down-converting stage comprising a second mixer 520 and a second local oscillator (LO) comprising DRO 524 (of the same type as DRO 100 and/or 400), optional amplifier 522 (or other device that isolates the output of the DRO 524 from the mixer 520, such as an attenuator or isolator), phase lock loop (PLL) 526, and the reference crystal oscillator 508 (being common to both down-converting stages). The output of the DRO 524 is optionally coupled to the input of the amplifier 522, as required, for increasing the power of the local oscillator signal sufficiently to drive the mixer 520. A portion of the local oscillator signal at the input of the mixer 520 is coupled to the PLL 526 to phase compare the local oscillator signal with the reference from the crystal oscillator 508, and to generate a tuning voltage V_{TUNE} for the DRO 524 to keep the DRO output within a frequency specification. The output of the mixer 520 is coupled to a baseband frequency filter 530 to remove the higher frequency products and other unwanted signals from the second down-converted received signal to generate a baseband signal.

FIG. 6 illustrates a block diagram of an exemplary transmitter 600 using one or more dielectric resonator oscillators (DROS) in accordance with the invention. The DROs 100 and 400 of the invention can be used in many applications, even as part of the transmitter 600. The transmitter 600 comprises a first up-converting stage for up-converting a baseband signal. The first up-converting stage comprising a first mixer 602 and a first local oscillator (LO) comprising DRO 610 (of the same type as DRO 100 and/or 400), optional amplifier 608 (or other device that isolates the output of the DRO 610 from the mixer 602, such as an attenuator or isolator), phase lock loop (PLL) 606, and a reference crystal oscillator 604. The output of the DRO 610 is optionally coupled to the input of the amplifier 608, as required, for increasing the power of the local oscillator signal sufficiently to drive the mixer 602. A portion of the local oscillator signal at the input of the mixer 602 is coupled to the PLL 606 to phase compare the local oscillator signal with the reference from the crystal oscillator 604, and to generate a tuning voltage V_{TUNE} for the DRO 610 to keep the DRO output within a frequency specification.

The output of the mixer 602 is coupled to an intermediate frequency (IF) filter 612 to remove the lower frequency products and other unwanted signals from the up-converted signal. If two-stage up-conversion is desired, the output of the IF filter 612 is coupled to a second up-converting stage comprising a second mixer 614 and a second local oscillator (LO) comprising DRO 618 (of the same type as DRO 100 and/or 400), optional amplifier 616 (or other device that isolates the output of the DRO 618 from the mixer 614, such as an attenuator or isolator), phase lock loop (PLL) 620, and the reference crystal oscillator 604 (being common to both up-converting stages). The output of the DRO 618 is optionally coupled to the input of the amplifier 616, as required, for increasing the power of the local oscillator signal sufficiently to drive the mixer 614. A portion of the local oscillator signal at the input of the mixer 614 is coupled to the PLL 620 to phase compare the local oscillator signal with the reference from the crystal oscillator 604, and to generate a tuning voltage V_{TUNE} for the DRO 618 to keep the DRO output within a frequency specification.

The output of the mixer 614 is coupled to a radio frequency (RF)/microwave/millimeterwave filter 624 to remove the lower frequency products and other unwanted signals from the second up-converted signal to generate the RF/microwave/millimeterwave signal for transmission via a wireless medium or other transmission medium. The output of the RF/microwave/millimeterwave filter 624 is coupled to the input of a power amplifier 626 (which can comprise one or more amplification stages) for increasing the power of the RF/microwave/millimeterwave signal for transmission over the wireless medium via the antenna 628 or transmission over other types of transmission mediums.

In the foregoing specification, the invention has been described with reference to specific embodiments thereof. It will, however, be evident that various modifications and changes may be made thereto departing from the broader spirit and scope of the invention. The specification and drawings are, accordingly, to be regarded in an illustrative rather than a restrictive sense.

### Appendix A

I hereby appoint BLAKELY, SOKOLOFF, TAYLOR & ZAFMAN LLP, a firm including: William E. Alford, Reg. No. 37,764; Farzad E. Amini, Reg. No. 42,261; William Thomas Babbitt, Reg. No. 39,591; Carol F. Barry, Reg. No. 41,600; Jordan Michael Becker, Reg. No. 39,602; Lisa N. Benado, Reg. No. 39,995; Bradley J. Bereznak, Reg. No. 33,474; Michael A. Bemadicou, Reg. No. 35,934; Roger W. Blakely, Jr., Reg. No. 25,831; R. Alan Burnett, Reg. No.46,149; Gregory D. Caldwell, Reg. No. 39,926; Andrew C. Chen, Reg. No. 43,544; Thomas M. Coester, Reg. No. 39,637; Donna Jo Coningsby, Reg. No. 41,684; Dennis M. deGuzman, Reg. No. 41,702; Justin Dillon, Reg. No. 42,486; Stephen M. De Klerk, Reg. No. P46,503; Michael Anthony DeSanctis, Reg. No. 39,957; Daniel M. De Vos, Reg. No. 37,813; Sanjeet Dutta, Reg. No. P46,145; Matthew C. Fagan, Reg. No. 37,542; Tarek N. Fahmi, Reg. No. 41,402; George Fountain, Reg. No. 36,374; Paramita Ghosh, Reg. No. 42,806; James Y. Go, Reg. No. 40,621; James A. Henry, Reg. No. 41,064; Willmore F. Holbrow III, Reg. No. P41,845; Sheryl Sue Holloway, Reg. No. 37,850; George W Hoover II, Reg. No. 32,992; Eric S. Hyrnan, Reg. No. 30,139; William W. Kidd, Reg. No. 31,772; Sang Hui Kim, Reg. No. 40,450; Walter T. Kim, Reg. No. 42,731; Eric T. King, Reg. No. 44,188; Erica W. Kuo, Reg. No. 42,775; George B. Leavell, Reg. No. 45,436; Gordon R. Lindeen III, Reg. No. 33,192; Jan Carol Little, Reg. No. 41,181; Robert G. Litts, Reg. No. 46,876; Kurt P. Leyendecker, Reg. No. 42,799; Julio Loza, Reg. No. P-47,758; Joseph Lutz, Reg. No. 43,765; Michael J. Mallie, Reg. No. 36,591; Andre L. Marais, under 37 C.F.R. §10.9(b); Paul A. Mendonsa, Reg. No. 42,879; Clive D. Menezes, Reg. No. 45,493; Chun M. Ng, Reg. No. 36,878; Thien T. Nguyen, Reg. No. 43,835; Thinh V. Nguyen, Reg. No. 42,034; Dennis A. Nicholls, Reg. No. 42,036; Daniel E. Ovanezian, Reg. No. 41,236; Kenneth B. Paley, Reg. No. 38,989; Marina Portnova, Reg. No. P45,750; Michael A. Proksch, Reg. No. 43,021; William F. Ryann, Reg. 44,313; James H. Salter, Reg. No. 35,668; William W. Schaal, Reg. No. 39,018; James C. Scheller, Reg. No. 31,195; Jeffrey S. Schubert, Reg. No. 43,098; George Simion, Reg. No. P-47,089; Jeffrey Sam Smith, Reg. No. 39,377; Maria McCormack Sobrino, Reg. No. 31,639; Stanley W. Sokoloff, Reg. No. 25,128; Judith A. Szepesi, Reg. No. 39,393; Vincent P. Tassinari, Reg. No. 42,179; Edwin H. Taylor, Reg. No. 25,129; John F. Travis, Reg. No. 43,203; Joseph A. Twarowski, Reg. No. 42,191; Kerry D. Tweet, Reg. No. 45,959; Mark C. Van Ness, Reg. No. 39,865; Thomas A. Van Zandt, Reg. No. 43,219; Lester J. Vincent, Reg. No. 31,460; Glenn E. Von Tersch, Reg. No. 41,364; John Patrick Ward, Reg. No. 40,216; Mark L. Watson, Reg. No. P46,322; Thomas C. Webster, Reg. No. P46,154; and Norman Zafman, Reg. No. 26,250; my patent attorneys, and Firasat Ali, Reg. No. 45,715; and Justin M. Dillon, Reg. No. 42,486; Raul Martinez, Reg. No.46,904; my patent agents, with offices located at 12400 Wilshire Boulevard, 7th Floor, Los Angeles, Calif. 90025, telephone (714) 557-3800, with full power of substitution and revocation, to prosecute this application and to transact all business in the Patent and Trademark Office connected herewith.

What it is claimed:

1. A dielectric resonator oscillator for generating a signal having an operating frequency, comprising:
a field effect transistor having a gate, a drain, and a source;
a dielectric resonator puck having a puck-resonator line interaction region;
a resonator transmission line having a first end coupled to said gate of said field effect transistor and a second end coupled to a grounded impedance element;
wherein a first electrical length at said operating frequency exists from a region interior to said field effect transistor to a first region on said resonator transmission line that is closest to said puck-resonator line interaction region;
wherein a second electrical length at said operating frequency exists along a first straight line extending from said first region on said resonator transmission line to said puck-resonator line interaction region; and
wherein a sum of said first and second electrical lengths is approximately 180 degrees or an integer multiple thereof.

2. The dielectric resonator oscillator of claim 1, wherein said resonator transmission line is configured as a microstrip transmission line.

3. The dielectric resonator oscillator of claim 1, wherein said grounded impedance element has a characteristic impedance substantially the same as a characteristic impedance of said resonator transmission line.

4. The dielectric resonator oscillator of claim 1, further comprising:
an output impedance matching circuit coupled to said drain of said field effect transistor;
a drain bias circuit for routing a drain bias voltage to said drain of said field effect transistor while substantially isolating said signal from said drain bias circuit;
a source feedback transmission line coupled to said source of said field effect transistor, wherein a third electrical length at said operating frequency of approximately 180 degrees or an integer multiple thereof exists between said interior region of said field effect transistor and a signal end of said source feedback transmission line; and
a source bias circuit for routing a source bias voltage to said source of said field effect transistor while substantially isolating said signal from said source bias circuit.

5. The dielectric resonator oscillator of claim 1, further comprising:
a varactor diode having an anode and a cathode;
a bypass device for substantially coupling a signal ground to said cathode of said varactor diode;
a tuning transmission line having an end coupled to said anode of said varactor diode;
wherein a third electrical length at said operating frequency exists from said signal ground to a second region on said tuning transmission line that is closest to a puck-tuning line interaction region of said dielectric resonator puck;
wherein a fourth electrical length at said operating frequency exists along a second straight line extending from said second region on said tuning transmission line to said puck-tuning line interaction region; and
wherein a sum of said third and fourth electrical lengths is approximately 90 degrees or an odd integer multiple thereof at substantially a center of a range of said sum resulting from said varactor diode being operated across a tuning voltage range.

6. The dielectric resonator oscillator of claim 5, wherein a fifth electrical length at said operating frequency exists along said tuning transmission line from an open end of said tuning transmission line to said second region such that the fifth electrical length causes said sum of said third and fourth electrical lengths to be approximately 90 degrees or an odd integer multiple thereof at substantially said center of sum range resulting from said varactor diode being operated across said tuning voltage range.

11. The method of claim 10, wherein said port of said field effect transistor is a gate.

12. The method of claim 9, wherein said transistor is a bipolar transistor.

13. The method of claim 12, wherein said port of said bipolar transistor is a base.

14. A dielectric resonator oscillator for generating a signal having an operating frequency, comprising:
a field effect transistor having a gate, a drain, and a source;
a dielectric resonator puck having a puck-tuning line interaction region;
a resonator transmission line having a first end coupled to said gate of said field effect transistor and a second end coupled to a grounded impedance element;
a varactor diode having first and second terminals;
a bypass device for substantially coupling a signal ground to said first terminal of said varactor diode;
a tuning transmission line having an open end and an end coupled to said second terminal of said varactor diode;
wherein a first electrical length at said operating frequency exists along said tuning transmission line from said signal ground to a first region on said tuning transmission line that is closest to said puck-tuning line interaction region of said dielectric resonator puck;
wherein a second electrical length at said operating frequency exists along a first straight line extending from said first region on said tuning transmission line to said puck-tuning line interaction region; and
wherein a sum of said first and second electrical lengths is approximately 90 degrees or an odd integer multiple thereof at substantially a center of a range of said sum resulting from said varactor diode being operated across a tuning voltage range.

15. The dielectric resonator oscillator of claim 14, wherein said tuning transmission line is configured as a microstrip transmission line.

16. The dielectric resonator oscillator of claim 14, wherein said grounded impedance element has a characteristic impedance substantially the same as a characteristic impedance of said resonator transmission line.

17. The dielectric resonator oscillator of claim 14, further comprising:
an output impedance matching circuit coupled to said drain of said field effect transistor;
a drain bias circuit for routing a drain bias voltage to said drain of said field effect transistor while substantially isolating said signal from said drain bias circuit;
a source feedback transmission line coupled to said source of said field effect transistor, wherein a third electrical length at said operating frequency of approximately 180 degrees or an integer multiple thereof exists between said interior region of said field effect transistor and a signal end of said source feedback transmission line; and
a source bias circuit for routing a source bias voltage to said source of said field effect transistor while substantially isolating said signal from said source bias circuit.

18. The dielectric resonator oscillator of claim 14:
wherein a third electrical length at said operating frequency exists along said resonator transmission line from a region interior to said field effect transistor to a second region on said resonator transmission line that is closest to a puck-resonator line interaction region of said dielectric resonator puck;
wherein a fourth electrical length at said operating frequency exists along a second straight line extending from said second region on said resonator transmission line to said puck-resonator line interaction region; and
wherein said third and fourth electrical lengths added together is approximately 180 degrees or an integer multiple thereof. 119. The dielectric resonator oscillator of claim 14, wherein a third electrical length at said operating frequency exists along said tuning transmission line from an open end of said tuning transmission line to said first region such that said third electrical length causes said sum of said first and second electrical lengths to be approximately 90 degrees or an odd integer multiple thereof at substantially said center of sum range resulting from said varactor diode being operated across said tuning voltage range.

20. The dielectric resonator oscillator of claim 14, further comprising:
a tune voltage bias circuit for routing a tune voltage to a cathode of said varactor diode while substantially isolating said signal from said tune bias circuit; and
a varactor grounding circuit for grounding an anode of said varactor diode while substantially isolating said signal from said varactor grounding circuit.

21. The dielectric resonator oscillator of claim 14, wherein said resonator transmission line is configured as a microstrip transmission line.

22. A method of designing a dielectric resonator oscillator that can generate a signal having an operating frequency, comprising:
providing a transistor having at least one port;
providing a dielectric resonator puck having a puck-tuning line interaction region;
providing a resonator transmission line having a first end coupled to said port of said transistor;
providing a varactor diode having first and second terminals;
providing a bypass device for substantially coupling a signal ground to said first terminal of said varactor diode;
providing a tuning transmission line having an open end and an end coupled to said varactor diode;
wherein a first electrical length at said operating frequency exists along said tuning transmission line from said signal ground to a first region on said tuning transmission line that is closest to said puck-tuning line interaction region of said dielectric resonator puck;
wherein a second electrical length at said operating frequency exists along a first straight line extending from said first region on said tuning transmission line to said puck-tuning line interaction region; and
wherein a sum of said first and second electrical lengths is approximately 90 degrees or an odd integer multiple thereof at substantially a center of a range of said sum resulting from said varactor diode being operated across a tuning voltage range.

23. The method of claim 22, wherein said transistor comprises a field effect transistor.

24. The method of claim 23, wherein said port of said field effect transistor is a gate.

25. The method of claim 22, wherein said transistor is a bipolar transistor.

26. The method of claim 25, wherein said port of said bipolar transistor is a base.

27. The method of claim 22, wherein a third electrical length at said operating frequency exists along said tuning transmission line from said open end of said tuning transmission line to said first region such that said third electrical length causes said sum of said first and second electrical lengths to be approximately 90 degrees or an odd integer multiple thereof at substantially said center of sum range resulting from said varactor diode being operated across said tuning voltage range.

28. A dielectric resonator oscillator for generating a signal having an operating frequency, comprising:
a field effect transistor having a gate, a drain, and a source;
a dielectric resonator puck having a puck-tuning line interaction region;
a resonator transmission line having a first end coupled to said gate of said field effect transistor and a second end coupled to a grounded impedance element; and
a source feedback transmission line coupled to said source of said field effect transistor, wherein an electrical length at said operating frequency of approximately 180 degrees or an integer multiple thereof exists between an interior region of said field effect transistor and a signal end of said source feedback transmission line.

29. The dielectric resonator oscillator of claim 28, wherein said source feedback transmission line is configured as a microstrip transmission line.

30. The dielectric resonator oscillator of claim 28, wherein said signal end of said source feedback transmission line is an open end.

31. The dielectric resonator oscillator of claim 28, wherein said signal end of said source feedback transmission line is a signal grounded end.

32. A method of designing a dielectric resonator oscillator that can generate a signal having an operating frequency, comprising:
providing a transistor having at least first and second ports;
providing a dielectric resonator puck having a puck-tuning line interaction region;
providing a resonator transmission line having a first end coupled to said first port of said transistor; and
providing a feedback transmission line coupled to said second port of said transistor, wherein an electrical length at said operating frequency of approximately 180 degrees or an integer multiple thereof exists between an interior region of said transistor and a signal end of said feedback transmission line.

33. The method of claim 32, wherein said transistor comprises a field effect transistor.

34. The method of claim 33, wherein said first port of said field effect transistor is a gate, and said second port of said field effect transistor is a source.

35. The method of claim 32, wherein said transistor is a bipolar transistor.

36. The method of claim 35, wherein said first port of said bipolar transistor is a base, and said second port of said bipolar transistor is an emitter.

37. A dielectric resonator oscillator for generating a signal having an operating frequency, comprising:
a field effect transistor having a gate, a drain, and a source;
a dielectric resonator puck; and
a resonator transmission line having a first end coupled to said gate of said field effect transistor and a second end coupled to a grounded impedance element;
wherein a first portion of said resonator transmission line is formed on a first substrate having a first relative dielectric constant, and a second portion of said resonator transmission line is formed on a second substrate having a second relative dielectric constant less than said first relative dielectric constant, wherein said second dielectric is situated closer to said dielectric resonator puck than said first dielectric.

38. The dielectric resonator oscillator of claim 37, wherein said first substrate comprises an alumina material.

39. The dielectric resonator oscillator of claim 37, wherein said second substrate comprises a quartz material.

40. The dielectric resonator oscillator of claim 37, wherein said first portion and/or said second portion of said resonator transmission line is configured as a microstrip transmission line.

41. The dielectric resonator oscillator of claim 37, further comprising:
an output impedance matching circuit coupled to said drain of said field effect transistor;
a drain bias circuit for routing a drain bias voltage to said drain of said field effect transistor while substantially isolating said signal from said drain bias circuit;
a source feedback transmission line coupled to said source of said field effect transistor; and
a source bias circuit for routing a source bias voltage to said source of said field effect transistor while substantially isolating said signal from said source bias circuit.

42. A method of designing a dielectric resonator oscillator that generates a signal having an operating frequency, comprising:
providing a transistor having at least one port;
providing a dielectric resonator puck;
providing a resonator transmission line having a first end coupled to said port of said transistor;
wherein a first portion of said resonator transmission line is formed on a first substrate having a first relative dielectric constant, and a second portion of said resonator transmission line is formed on a second substrate having a second relative dielectric constant less than said first relative dielectric constant, wherein said second dielectric is situated closer to said dielectric resonator puck than said first dielectric.

43. The method of claim 42, wherein said first substrate comprises an alumina material.

44. The method of claim 42, wherein said second substrate comprises a quartz material.

45. The method of claim 42, wherein said first portion and/or said second portion of said resonator transmission line is configured as a microstrip transmission line.

46. The method of claim 42, wherein said transistor comprises a field effect transistor.

47. The method of claim 46, wherein said port of said field effect transistor is a gate.

48. The method of claim 42, wherein said transistor is a bipolar transistor.

49. The method of claim 48, wherein said port of said bipolar transistor is a base.

50. A dielectric resonator oscillator for generating a signal having an operating frequency, comprising:
a field effect transistor having a gate, a drain, and a source;
a dielectric resonator puck;
a resonator transmission line having a first end coupled to said gate of said field effect transistor and a second end coupled to a grounded impedance element; and
a tuning transmission line having a first portion formed on a first substrate having a first dielectric constant, and a second portion formed on a second substrate having a second dielectric constant less than said first dielectric constant, wherein said second dielectric is situated closer to said dielectric resonator puck than said first dielectric.

51. The dielectric resonator oscillator of claim 50, wherein said first substrate comprises an alumina material.

52. The dielectric resonator oscillator of claim 50, wherein said second substrate comprises a quartz material.

53. The dielectric resonator oscillator of claim 50, wherein said first portion and/or said second portion of said resonator transmission line is configured as a microstrip transmission line.

54. The dielectric resonator oscillator of claim 50, further comprising:
an output impedance matching circuit coupled to said drain of said field effect transistor;
a drain bias circuit for routing a drain bias voltage to said drain of said field effect transistor while substantially isolating said signal from said drain bias circuit;
a source feedback transmission line coupled to said source of said field effect transistor; and
a source bias circuit for routing a source bias voltage to said source of said field effect transistor while substantially isolating said signal from said source bias circuit.

55. A method of designing a dielectric resonator oscillator that generates a signal having an operating frequency, comprising:
providing a transistor having at least one port;
providing a dielectric resonator puck;
providing a resonator transmission line having a first end coupled to said port of said transistor; and
providing a tuning transmission line having a first portion formed on a first substrate having a first dielectric constant, and a second portion formed on a second substrate having a second dielectric constant less than said first dielectric constant, wherein said second dielectric is situated closer to said dielectric resonator puck than said first dielectric.

56. The method of claim 55, wherein said first substrate comprises an alumina material.

57. The method of claim 55, wherein said second substrate comprises a quartz material.

58. The method of claim 55, wherein said first portion and/or said second portion of said resonator transmission line is configured as a microstrip transmission line.

59. The method of claim 55, wherein said transistor comprises a field effect transistor.

60. The method of claim 59, wherein said port of said field effect transistor is a gate.

61. The method of claim 55, wherein said transistor is a bipolar transistor.

62. The method of claim 61, wherein said port of said bipolar transistor is a base.

63. A receiver or transmitter having at least one dielectric resonator oscillator as defined in claims 1, 14, 28, 37 or 50.
